(19) United States
(12) Patent Application Publication
(10) Pub. No.: US 2024/0211743 A1
(43) Pub. Date: Jun. 27, 2024

(54) NEURON CIRCUIT AND METHOD WITH FIRING PATTERN

(71) Applicants: SAMSUNG ELECTRONICS CO., LTD., Suwon-si (KR); Seoul National University R&DB Foundation, Seoul (KR)

(72) Inventors: Sung Min LEE, Yongin-si (KR); Sangbum KIM, Seoul (KR)

(73) Assignees: SAMSUNG ELECTRONICS CO., LTD., Suwon-si (KR); Seoul National University R&DB Foundation, Seoul (KR)

(21) Appl. No.: 18/327,279

(22) Filed: Jun. 1, 2023

(30) Foreign Application Priority Data
Dec. 27, 2022 (KR) 10-2022-0186425

(51) Int. Cl. G06N 3/065; G06N 3/049

(52) U.S. Cl. CPC G06N 3/065; G06N 3/049

(57) ABSTRACT

A neuron circuit includes: a membrane circuit configured to receive a weighted synaptic current from a synaptic array and receive an adaptive current from an adaptive circuit; a comparator circuit configured to control a pulse generation circuit in response to a voltage of the membrane circuit exceeding a predetermined threshold voltage; the pulse generation circuit configured to control the membrane circuit and the adaptive circuit based on an output signal from the comparator circuit and generate a pulse comprising a firing pattern; and the adaptive circuit, connected to the membrane circuit and the pulse generation circuit, and configured to determine the firing pattern of the pulse generation circuit.

### CROSS-REFERENCE TO RELATED APPLICATIONS

This application claims the benefit under 35 USC § 119(a) of Korean Patent Application No. 10-2022-0186425, filed on Dec. 27, 2022 in the Korean Intellectual Property Office, the entire disclosure of which is incorporated herein by reference for all purposes.

### BACKGROUND

### 1. Field

The following description relates to a neuron circuit and method with firing pattern determination.

### 2. Description of Related Art

Spiking neural networks may mimic an operating method of a nervous system of an organism including an interaction between neurons. As the structure of a neural network becomes more complicated, a complexity and power loss of hardware implementing the neural network may increase.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a neuron circuit includes: a membrane circuit configured to receive a weighted synaptic current from a synaptic array and receive an adaptive current from an adaptive circuit; a comparator circuit configured to control a pulse generation circuit in response to a voltage of the membrane circuit exceeding a predetermined threshold voltage; the pulse generation circuit configured to control the membrane circuit and the adaptive circuit based on an output signal from the comparator circuit and generate a pulse comprising a firing pattern; and the adaptive circuit, connected to the membrane circuit and the pulse generation circuit, and configured to determine the firing pattern of the pulse generation circuit.

The adaptive circuit may be configured to transmit an adaptive current to the membrane circuit based on an adaptation time constant parameter, a subthreshold adaptation conductor parameter, and a spike-triggered adaptation current parameter of the adaptive circuit and determine the firing pattern.

The membrane circuit may be configured to receive the adaptive current from the adaptive circuit based on an adaptation time constant parameter of the membrane circuit and a reset voltage parameter of the membrane circuit and determine the firing pattern.

The membrane circuit and the adaptive circuit each may include a variable resistor element and a capacitor element.

The variable resistor of the membrane circuit and the variable resistor element of the adaptive circuit each may include either one or both of a phase change material (PCM) and resistive random access memory (RRAM).

The variable resistor element of the membrane circuit and the variable resistor element of the adaptive circuit each may include an indium-gallium-zinc-oxide (IGZO) transistor.

The pulse generation circuit may be configured to perform an operation of controlling the membrane circuit by changing a voltage of the membrane circuit to a reset voltage based on a feedback spike.

The pulse generation circuit may be configured to perform an operation of controlling the adaptive circuit by charging an adaptive capacitor comprised in the adaptive circuit based on a feedback spike.

The pulse generation circuit may include a plurality of positive channel metal-oxide semiconductors (PMOSs) and a plurality of negative channel metal-oxide semiconductors (NMOSs).

The pulse generation circuit may be configured to perform an operation of applying a pulse to the adaptive circuit based on a common voltage and an output voltage.

The pulse generation circuit may correspond to a digital pulse generation circuit.

A voltage value of a capacitor element of the adaptive circuit may be proportional to a voltage value of a capacitor element of the membrane circuit.

A capacitor element of the adaptive circuit may be configured to decrease a voltage value of a capacitor element of the membrane circuit.

In one or more general aspects, a processor-implemented method with neuron circuit control includes: receiving one or more parameter values determining a firing pattern based on a membrane circuit and an adaptive circuit comprised in a neuron circuit; and outputting a voltage comprising a spiking firing pattern based on the received one or more parameter values.

The one or more parameter values may include any one or any combination of any two or more of an adaptation time constant parameter of the adaptive circuit, a reset voltage parameter of the membrane circuit, a subthreshold adaptation conductor parameter, and a spike-triggered adaptation current parameter of the adaptive circuit and determine the firing pattern.

In one or more general aspects, a non-transitory computer-readable storage medium stores instructions that, when executed by a processor, configure the processor to perform any one, any combination, or all of operations and/or methods described herein.

In one or more general aspects, a neuron circuit includes: a membrane circuit comprising a variable resistor element and configured to receive a weighted synaptic current from a synaptic array and receive an adaptive current from an adaptive circuit; a pulse generation circuit configured to control the membrane circuit and the adaptive circuit and generate a pulse comprising a firing pattern; and the adaptive circuit comprising another variable resistor element, connected to the membrane circuit and the pulse generation circuit, and configured to determine the firing pattern of the pulse generation circuit.

The neuron circuit may include a comparator circuit configured to control the pulse generation circuit in response to a voltage of the membrane circuit exceeding a predetermined threshold voltage.

The adaptive circuit may be configured to adjust the other variable resistor element based on one or more parameters of a neuron model.

The membrane circuit may be configured to adjust the variable resistor element based on one or more parameters of a neuron model.

Other features and aspects will be apparent from the following detailed description, the drawings, and the claims.

### BRIEF DESCRIPTION OF THE DRAWINGS

FIG. 1 illustrates an example of a neuron model and an operation thereof.

FIG. 2 illustrates an example of a neural network according to an example.

FIG. 3 illustrates an example of a configuration of a neuron circuit according to an example.

FIGS. 4A and 4B illustrate an example of a key parameter of a neuron circuit according to an example.

FIG. 5 illustrates an example of an operation of a neuron circuit in response to current application from a synaptic array when the neuron circuit is implemented in analog elements, according to an example.

FIG. 6A and FIG. 6B illustrate examples of implementing a variable resistor in a neuron circuit, according to an example.

FIG. 7 illustrates an example of an operation of a neuron circuit in response to current application from a synaptic array when the neuron circuit is implemented in digital elements, according to an example.

FIG. 8 illustrates an example of a method of controlling a neuron circuit, according to an example.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only and is not to be limiting of the examples. The singular forms “a”, “an”, and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and based on an understanding of the disclosure of the present application. It will be further understood that terms, such as those defined in commonly-used dictionaries, should be interpreted as having a meaning that is consistent with their meaning in the context of the relevant art and the disclosure of the present application, and will not be interpreted in an idealized or overly formal sense unless expressly so defined herein.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Hereinafter, examples will be described in detail with reference to the accompanying drawings. When describing the examples with reference to the accompanying drawings, like reference numerals refer to like components and a repeated description related thereto will be omitted.

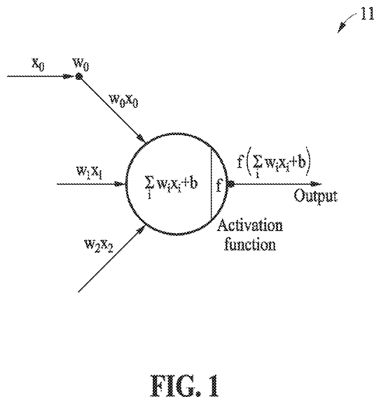

FIG. 1 illustrates an example of a neuron model and an operation thereof.

A neuron model 11 may implement a neuromorphic operation including a multiplication operation that multiplies information from a plurality of neurons by a synaptic weight, an addition operation Σ on values ω₀x₀, ω₁x₁, and ω₂x₂ multiplied by the synaptic weight, and an operation that applies the characteristic function b and the activation function f to the result of the addition operation. Neuromorphic operation results may be provided by the neuromorphic operation. Here, values such as x₀, x₁, x₂, . . . may be referred to as axon values, and values such as ω₀, ω₁, ω₂, . . . may be referred to as synaptic weights.

An AdEx neuron model may correspond to a neuron model defined by Equation 1 shown below, for example.

$$C \frac{d V}{d t} = - {g}_{L} ( V - {E}_{L} ) + {g}_{L} {Δ}_{T} exp ( \frac{V - {V}_{T}}{{Δ}_{T}} ) + I - W \qquad Equation 1$$

$${τ}_{w} \frac{d w}{d t} = a ( V - {E}_{L} ) - w$$

$$if V > 0 mV then \{ \begin{matrix}V \to {V}_{r} \\ w \to {w}_{r} = w + b\end{matrix}$$

In this case, C may denote the capacity of a membrane capacitor included in a membrane circuit included in a neuron model. V may denote a voltage of a capacitor included in the membrane circuit included in the neuron model. E_{L} may denote a leak reversal potential. g_{L} may denote leak conductance. I may denote a current of the membrane capacitor included in the membrane circuit included in the neuron model. w may denote an adaptive current. τ_{w} may denote an adaptation time constant. a may denote subthreshold adaptation conductor and b may denote a spike-triggered adaptation current. When a voltage of the membrane capacitor exceeds 0 mV (exceeds a threshold voltage), the voltage of the membrane capacitor may be Vᵣ denoting a resting voltage (or a reset voltage) and in this case, an adaptive current wᵣ in a resting state may be a value obtained by adding a spike-triggered adaptation current to the adaptive current. Herein, such reference to “neurons,” “axons,” “synapses,” “membranes,” “neural networks,” etc. is not intended to impart any relatedness with respect to how the neuron model and/or neural network architecture computationally maps or thereby intuitively recognizes information and how biological neurons operate. I.e., the terms are merely terms of art referring to the hardware-implemented neuron model and/or neural network architecture.

Because the voltage rapidly increases while an action potential increases, a parameter a may explain that a combination of the voltage and adaptation of the neuron model may contribute to spike-triggered adaptation. Based on the assumption that calcium influx mainly occurs during the action potential of the neuron model, an effect of a calcium dependent potassium channel may be explained by a spike-triggered adaptation current parameter b.

As shown in Equation 1, unlike a typical leaky-integrate-fire (LIF) neuron, the AdEx neuron model may define a differential equation expressing dynamics of an adaptive voltage. The AdEx neuron model may express an adaptive voltage of the neuron model by reflecting dynamics of a membrane potential through the defined differential equation. Through the AdEx neuron model, v-w dynamics may be realized by a phase plane analysis and various spiking firing patterns may be implemented in the same model by adjusting a parameter.

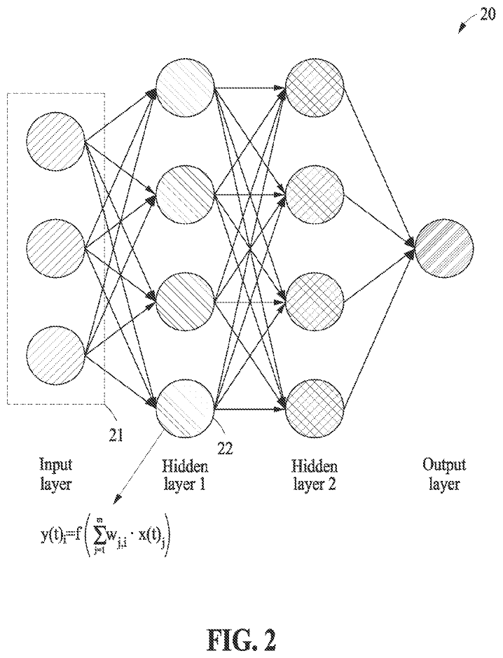

FIG. 2 illustrates an example of a neural network according to an example.

Referring to FIG. 2, a neural network 20 may be an example of an artificial neural network comprising the neuron model described above and may correspond to a deep neural network (DNN). For ease of description, the example that the neural network 20 includes two hidden layers is illustrated. However, the neural network 20 may include other numbers of hidden layers. For example, the neural network 20 may include three or more hidden layers. In addition, although the neural network 20 is illustrated in FIG. 2 as including a separate input layer 21 to receive input data, the input data may be directly input to a hidden layer.

In the neural network 20, artificial nodes of layers other than an output layer may be connected to artificial nodes of a subsequent layer via links to transmit an output signal. Values obtained by multiplying node values of artificial nodes included in the previous layer by weights allocated to each link may be input to one artificial node via the links. Node values of the previous layer may correspond to axon values and the weights may correspond to synaptic weights. The weight may be referred to as a parameter of the neural network 20. The activation function may include sigmoid, hyperbolic tangent (tanh), and rectified linear unit (ReLU), and nonlinearity of the neural network 20 may be formed by the activation function.

An output of one arbitrary node 22 included in the neural network 20 may be expressed by Equation 2 below, for example.

$${y ( t )}_{i} = f ( {\sum }_{j = 1}^{m} {w}_{j , i} {x ( t )}_{j} ) \qquad Equation 2$$

Equation 2 may denote an output value at a time t of an i-th node for m input values in an arbitrary layer. x(t)ⱼ may denote an output value at the time t of a j-th node of the previous layer and w_{j,i} may denote a weight applied to a connection part of the j-th node of the previous layer and the i-th node of the current layer. f( ) may denote an activation function. As shown in Equation 2, for the activation function, a multiply-accumulate result of an input value x(t)ⱼ and a weight w_{j,i} may be used. In other words, a multiply-accumulate (MAC) operation of an appropriate input value x(t)ⱼ and a weight w_{j,i} at a desired time point may be repeated. In addition to the use, various application fields requiring the MAC operation may exist and for this purpose, a processing unit that may process the MAC operation in an analog circuit area may be used.

A neuron of a neural network may include a combination of weights or biases. The neural network may include a plurality of neurons or a plurality of layers constituted by nodes. The neural network may infer a desired result from a predetermined input by changing the weights of the neurons through training.

The neural network may include a DNN. The neural network may include a convolutional neural network (CNN), a recurrent neural network (RNN), a perceptron, a multilayer perceptron, a feed forward (FF) network, a radial basis function (RBF) network, a deep feed forward (DFF) network, a long short-term memory (LSTM), a gated recurrent unit (GRU), an auto encoder (AE), a variational auto encoder (VAE), a denoising auto encoder (DAE), a sparse auto encoder (SAE), a Markov chain (MC), a Hopfield network (HN), a Boltzmann machine (BM), a restricted Boltzmann machine (RBM), a deep belief network (DBN), a deep convolutional network (DCN), a deconvolutional network (DN), a deep convolutional inverse graphics network (DCIGN), a generative adversarial network (GAN), a liquid state machine (LSM), an extreme learning machine (ELM), an echo state network (ESN), a deep residual network (DRN), a differentiable neural computer (DNC), a neural turning machine (NTM), a capsule network (CN), a Kohonen network (KN), and/or an attention network (AN).

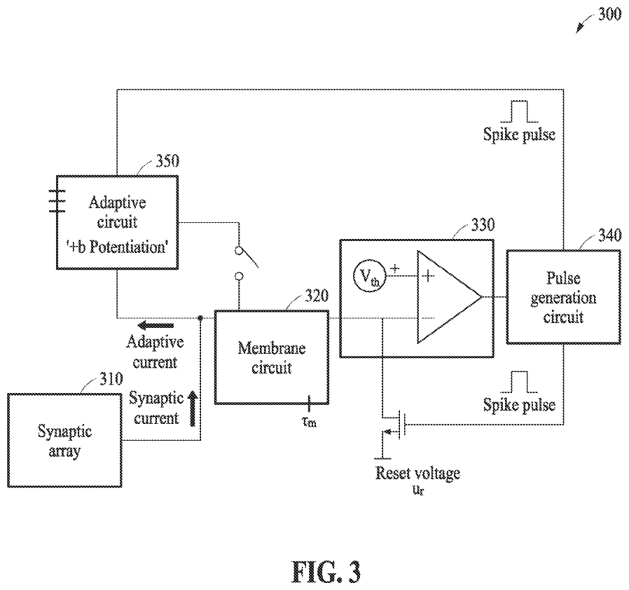

FIG. 3 illustrates an example of a configuration of a neuron circuit according to an example.

When a circuit is implemented by only analog elements without a digital element, an analog neuron circuit that causes a phenomenon in which a time interval between output spikes increases in response to feedback from an output spike, e.g., adaptation or an adaptive firing pattern. In addition, an analog neuron circuit that adjusts a threshold voltage may be implemented by using phase change memory (PCM) programming and a method of adjusting a potential of an adaptive capacitor with a back gate effect by reflecting the potential of the adaptive capacitor in a metal oxide semiconductor (MOSFET) that implements the potential of the adaptive capacitor in a synaptic current. However, in a typical analog neuron circuit, unlike the method of subtracting an adaptive voltage from a membrane potential like the AdEx neuron model, another spiking firing pattern may not be formed in the same circuit and programming of a neuron operation in response to a predetermined signal may not be available.

A hybrid circuit representing circuit components, such as an exponential circuit, may be implemented by combining digital and analog components. However, because a neuromorphic chip used to implement a circuit implements hundreds to thousands of neurons, a typical hybrid circuit may not be suitable for space and power efficiency of the circuit.

Furthermore, a typical complementary metal oxide semiconductor (CMOS)-based analog neuron circuit may be used to increase the size of a capacitor due to an off-state current of a MOSFET, which may lead to spatial limitation when implemented in hardware. Due to characteristics of the typical neuron model that temporarily stores an accurate potential and behaves, an off-state current through CMOS may cause a critical loss of information in the neuromorphic circuit.

Parameters, such as τ_{w}, a, and b of an adaptive circuit, τₘ of a membrane circuit, and a reset voltage uᵣ, may be programmed by implementing predetermined portions in a programmable resistance through the neuron circuit of one or more embodiments. The programming may be implemented by hardware of an element included in the neuron circuit. An analog neuron circuit platform may be implemented, wherein the analog neuron circuit platform may implement various spiking firing patterns including an adaptive firing pattern and a bursting firing pattern in the same circuit through programming of a parameter. Furthermore, the neuron circuit may be a circuit designed based on a negative metal oxide semiconductor (NMOS) and may include an indium-gallium-zinc-oxide (IGZO) thin-film transistor (TFT) as the NMOS as a component. The neuron circuit of one or more embodiments may minimize an off-state current by implementing a point in which an off-state current of a capacitor may flow as an IGZO transistor. Space efficiency may increase when the size of a capacitor decreases by minimizing an off-state current and the capacitor is implemented in hardware. An electric charge stored in the capacitor may be maintained relatively long by fitting the stored electric charge to a time unit (maximum milliseconds).

When an internal property of a neuron changes based on a neuromorphic computing structure or a predetermined signal (e.g., a neuromodulator), the neuron circuit of one or more embodiments may be used for spike coding of a neuromorphic system or may be used to adjust neuroplasticity.

Referring to FIG. 3, a neuron circuit 300 may include a synaptic array 310, a membrane circuit 320, a comparator circuit 330, a pulse generation circuit 340, and an adaptive circuit 350. The neuron circuit 300 in an example may receive a synaptic current on which weighted addition has been performed from the synaptic array 310 and may include the membrane circuit 320 that receives an adaptive current from the adaptive circuit 350. The membrane circuit 320 may receive an adaptive current from the adaptive circuit 350 based on an adaptation time constant parameter of the membrane circuit 320 and a reset voltage parameter of the membrane circuit 320 and may determine a firing pattern.

The comparator circuit 330 may control the pulse generation circuit 340 when a voltage of the membrane circuit 320 exceeds a predetermined threshold voltage. The pulse generation circuit 340 may control the membrane circuit 320 and the adaptive circuit 350 based on an output signal from the comparator circuit 330 and may generate a pulse having a firing pattern. The pulse generation circuit 340 may perform an operation of controlling the membrane circuit 320 by changing a voltage of the membrane circuit 320 to a reset voltage based on a feedback spike. The pulse generation circuit 340 may perform an operation of controlling the adaptive circuit 350 by charging an adaptive capacitor included in the adaptive circuit 350 based on a feedback spike. The pulse generation circuit 340 may include positive channel metal-oxide semiconductors (PMOSs) and negative channel metal-oxide semiconductors (NMOSs). The pulse generation circuit 340 may perform an operation of applying a pulse to the adaptive circuit 350 based on a common voltage and an output voltage. The pulse generation circuit 340 may be a digital pulse generation circuit.

The adaptive circuit 350 may be connected to the membrane circuit 320 and the pulse generation circuit 340 and may determine a firing pattern of the pulse generation circuit 340. The adaptive circuit 350 may transmit an adaptive current to the membrane circuit 320 based on an adaptation time constant parameter, a subthreshold adaptation conductor parameter, and a spike-triggered adaptation current parameter of the adaptive circuit 350 and may determine a firing pattern.

The adaptive circuit 350 and the membrane circuit 320 of the neuron circuit 300 may each include a variable resistor element and a capacitor element. A voltage of a membrane capacitor of the membrane circuit 320 may increase by applying a synaptic current from the synaptic array 310 to the membrane circuit 320. When the voltage of the membrane capacitor reaches a predetermined threshold voltage, a spike may be generated by the pulse generation circuit 340 based on a signal received from the comparator circuit 330. When a feedback spike is generated by the pulse generation circuit 340 due to the spike from the pulse generation circuit 340, the voltage of the membrane capacitor of the membrane circuit 320 may be changed to the reset voltage. In addition, when a feedback spike is generated by the pulse generation circuit 340 due to the spike from the pulse generation circuit 340, a voltage of an adaptive capacitor of the adaptive circuit 350 may increase through the feedback spike. The voltage of a capacitor element (e.g., of the adaptive capacitor) of the adaptive circuit 350 may be proportional to the voltage of a capacitor element (e.g., of the membrane capacitor) of the membrane circuit 320. The capacitor element of the adaptive circuit 350 may decrease the voltage of the capacitor element of the membrane circuit 320.

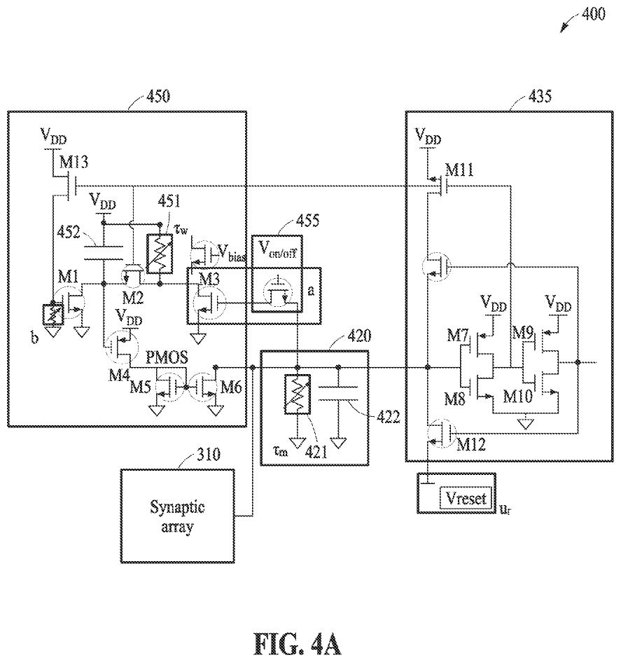

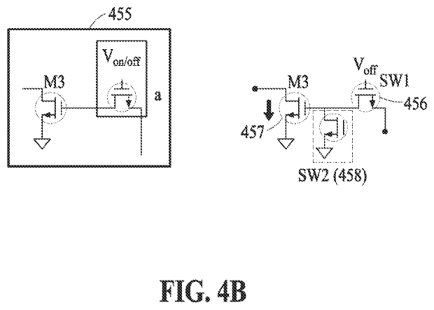

FIGS. 4A and 4B illustrate an example of a key parameter of a neuron circuit according to an example.

Referring to FIG. 4A, a configuration of a neuron circuit 400 is shown. A membrane circuit 420 of the neuron circuit 400 may include a variable resistor 421 and a capacitor element 422, and an adaptive circuit 450 of the neuron circuit 400 may include a variable resistor 451 and a capacitor element 452. The variable resistor 421 of the membrane circuit 420 and the variable resistor 451 of the adaptive circuit 450 of the neuron circuit 400 may each include non-volatile memory, e.g., a phase change material (PCM) and/or resistive random access memory (RRAM). The variable resistor 421 of the membrane circuit 420 and the variable resistor 451 of the adaptive circuit 450 of the neuron circuit 400 may each include an IGZO transistor, e.g., an NMOS transistor.

IGZO may be a material used as an active layer of a TFT, may be a compound consisting of four elements (indium, gallium, zinc, and oxygen) in a predetermined ratio, and may have semiconductor characteristics of high electron mobility. The IGZO transistor used in the neuron circuit 400 may be implemented by applying a bias voltage to a gate of a transistor. Because an off-state current of the IGZO transistor is small, a resistance greater than or equal to mega ohms MΩ may be implemented when a predetermined bias voltage is applied to a gate of the IGZO transistor. Through this, the neuron circuit 400 may have a time constant value in the unit of milliseconds.

Because a predetermined part (e.g., the variable resistor 421) of the membrane circuit 420 included in the neuron circuit 400 is constituted by a programmable resistance, τₘ that is an adaptation time constant and uᵣ that is a reset voltage of a membrane circuit may be adjusted through parameter programming.

Because a predetermined part (e.g., the variable resistor 451) of the adaptive circuit 450 included in the neuron circuit 400 is constituted by a programmable resistance, Tw that is an adaptation time constant, a that is a subthreshold adaptation conductor, and b that is a spike-triggered adaptation current of an adaptive circuit may be adjusted through parameter programming. By adjusting such parameters, the neuron circuit 400 may obtain an output having various spiking firing patterns through a pulse generation circuit 435.

Referring to FIG. 4B, an example of implementation of a subthreshold adaptation conductor a is shown.

In a case of a reflection implementing the subthreshold adaptation conductor a in a circuit part 455 of the neuron circuit 400, the subthreshold adaptation conductor a may be implemented by reflecting a parameter table of an AdEx neuron model. A switch SW1 456 of the subthreshold adaptation conductor a may be switched on based on the subthreshold adaptation conductor a.

The circuit part 455 of the neuron circuit 400 may change a spiking firing pattern of the neuron circuit 400 in real-time by alternately switching the SW1 456 and a switch SW2 458 of the circuit part 455. The SW2 458 may be used to prevent a transistor M3 457 of the circuit part 455 from operating as a metal oxide semiconductor capacitor (MOSCAP) as a current is applied to the transistor M3 457.

When a synaptic input current is applied to neuron circuit 400 at a constant current value while changing a main parameter of the neuron circuit 400, an adaptive firing pattern in which a gap between output spikes increases may appear. In addition, a bursting firing pattern in which an output spike at a high frequency appears at the beginning of an input and the output spike no longer appears may appear. However, the example is not limited thereto.

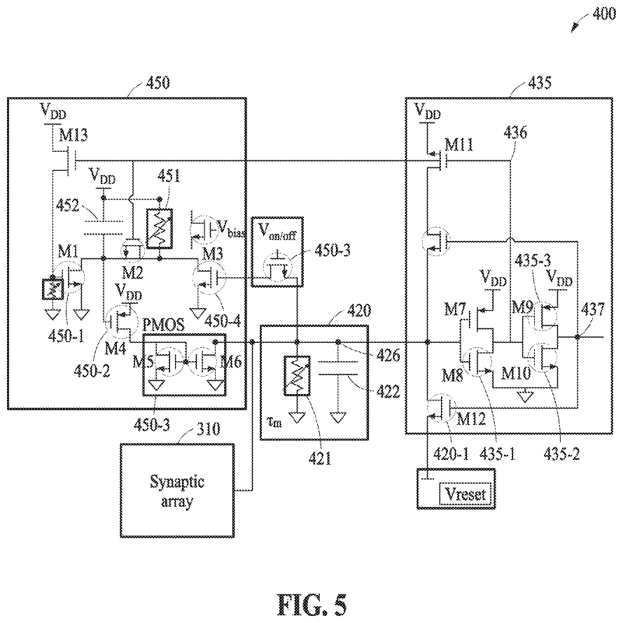

FIG. 5 illustrates an example of an operation of a neuron circuit in response to current application from a synaptic array when the neuron circuit is implemented in analog elements, according to an example.

Referring to FIG. 5, a synaptic current weighted from the synaptic array 310 and an adaptive current reflecting the size of a potential of an adaptive capacitor may be applied to the membrane capacitor 422 included in the membrane circuit 420.

When a voltage of the membrane capacitor 422 included in the membrane circuit 420 exceeds a threshold voltage of the pulse generation circuit 435, a transistor M8 435-1 may be turned on and a common voltage 436 may decrease. As the common voltage 436 decreases, a transistor M11 may be turned on due to a change in a gate voltage of the transistor M11. Accordingly, a membrane voltage 426 of the membrane capacitor 422 included in the membrane circuit 420 may rapidly increase and such phenomenon may be realized by implementing an exponential leaky-integrated-fire (ELIF) neuron model.

As a transistor M2 is turned off and a transistor M1 450-1 is turned on due to a change in a gate voltage while the common voltage 436 decreases, a voltage of the adaptive capacitor 452 included in the adaptive circuit 450 may increase. Such phenomenon may be reflected in a manner in which V_{w} decreases due to a spike-triggered adaptation current b. As described above, a so-called a “+b potentiation” operation may be implemented by floating the adaptive capacitor 452 using a switch transistor (e.g., the transistor M1 450-1) in the adaptive circuit 450 and then applying a predetermined charge value to the adaptive capacitor 452 by applying a pulse to the adaptive capacitor 452.

As a transistor M10 435-2 is turned off and a transistor M9 435-3 is turned on while the common voltage 436 decreases, an output voltage 437 may increase. Subsequently, as a transistor M12 420-1 is turned on while the output voltage 437 increases, the membrane voltage 426 may decrease to a reset voltage and the output voltage 437 may decrease as the common voltage 436 increases.

An transistor M4 450-2 may reflect an influence due to an adaptive current in the membrane voltage 426 through a current mirror 450-3 of M5 and M6. A transistor M3 450-4 may read the membrane voltage 426 and may reflect an influence therefrom in a resting voltage V_{w}. This may represent that a combination a voltage and adaptation of the neuron model through a parameter a may contribute to spike-triggered adaptation because a voltage rapidly increases while an action potential increases. As described above, the so-called “*a reflection” operation may be implemented by reflecting the membrane voltage 426 that is a voltage of the membrane capacitor 422 in the adaptive capacitor 452 through a read transistor (e.g., the M3 450-4) of the adaptive circuit 450.

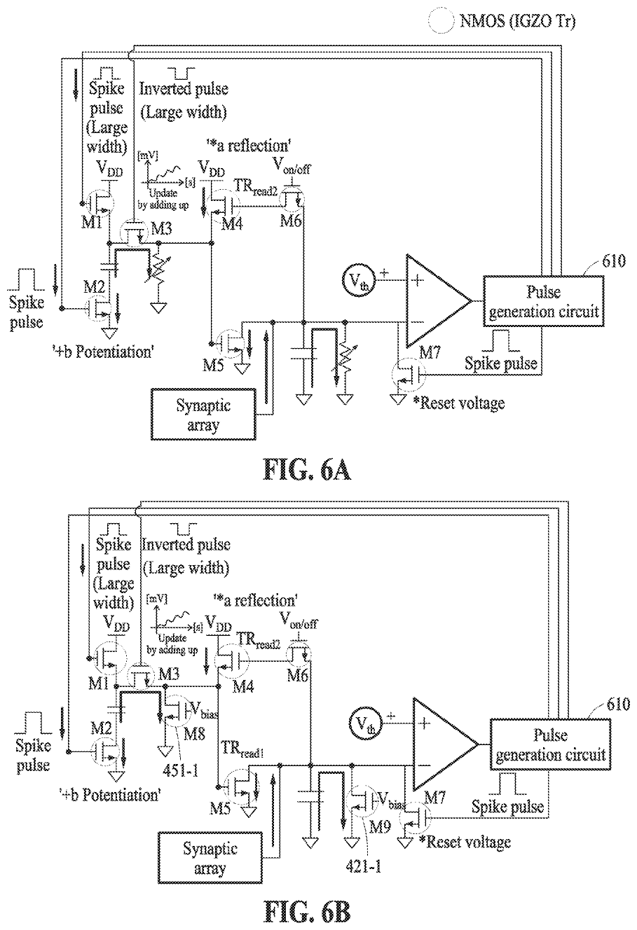

FIG. 6A and FIG. 6B illustrate examples of implementing a variable resistor in a neuron circuit, according to an example.

Referring to FIG. 6A, unlike the examples of FIGS. 4A to 5 using an analog pulse generation circuit including a plurality of PMOSs and a plurality of NMOSs, an example of implementing a neuron circuit using a digital pulse generation circuit 610 that performs pulse width modulation on a digital pulse is shown. When a pulse is applied to a circuit through the digital pulse generation circuit 610 of a neuron circuit of one or more embodiments, the neuron circuit of one or more embodiments may obtain a more accurate spiking firing pattern compared to a neuron circuit that uses the analog pulse generation circuit including the plurality of PMOSs and the plurality of NMOSs shown in FIGS. 4A to 5.

Referring to FIG. 6B, a neuron circuit may include an NMOS including the digital pulse generation circuit 610 and an IGZO transistor. The neuron circuit of one or more embodiments of FIG. 6B may use IGZO transistors 421-1 and 451-1 having the aforementioned characteristics to minimize an off-state current, unlike the examples of FIGS. 4A to 5 in which the neuron circuit uses a resistor as the variable resistor 420-1 in the membrane circuit 420 and uses a resistor as the variable resistor 451 in the adaptive circuit 450.

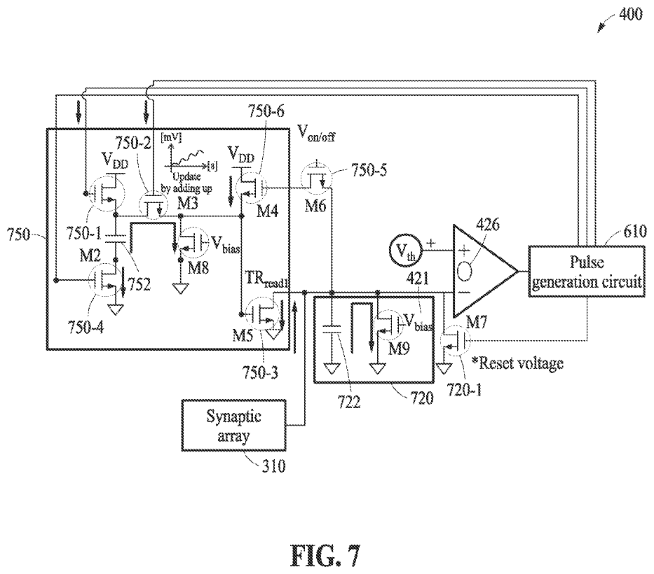

FIG. 7 illustrates an example of an operation of a neuron circuit in response to current application from a synaptic array when the neuron circuit is implemented in digital elements, according to an example.

Referring to FIG. 7, a synaptic current weighted from a synaptic array 310 and an adaptive current reflecting the size of a potential of an adaptive capacitor 752 included in an adaptive circuit 750 may be applied to a membrane capacitor 722 included in a membrane circuit 720 as shown in FIG. 7.

When a voltage of the membrane capacitor 722 exceeds a threshold potential, a spike may be output from the pulse generation circuit 610 through the comparator circuit 330.

When the spike is output from the pulse generation circuit 610, as a transistor M7 720-1 is turned on, a voltage of the membrane capacitor 722 may be induced to a reset voltage.

When the spike is output from the pulse generation circuit 610, a fed-back large spike pulse may turn on a transistor M1 750-1 and a fed-back inverted large pulse may turn on a transistor M3 750-2. In this case, when a high voltage VDD is applied to the membrane circuit through a transistor M5 750-3 while the transistor M1 750-1 is turned on, because the voltage of the membrane capacitor 722 has been already induced to the reset voltage due to the transistor M7 720-1, the two transistors M5 750-3 and M7 720-1 may compete for a voltage to be applied to the membrane capacitor 722. However, because an influence of the transistor M7 720-1 on the membrane capacitor 722 is greater than an influence of the transistor M5 750-3, the voltage of the membrane capacitor 722 may be induced to the reset voltage.

A voltage capacitor 752 may increase as an electric charge is filled in the adaptive capacitor 752 of the adaptive circuit 750 because a spike pulse is applied to a transistor M2 750-4, and a current due to the transistor M2 750-4 may be reflected in the adaptive capacitor 752 of the adaptive circuit 750 by stably turning off the transistor M6 750-5, and accordingly, “+b potentiation” may be implemented.

Subsequently, the transistor M5 750-3 may read a voltage of the adaptive capacitor 752 of the adaptive circuit 750 and may reflect a voltage of the adaptive capacitor 752 in the membrane circuit 720. When the transistor M6 750-5 is turned on, an influence of a voltage of the membrane capacitor 722 of the membrane circuit 720 may be reflected in the adaptive capacitor 752 included in the adaptive circuit 750 through a transistor M4 750-6 and accordingly, “*a reflection” may be implemented.

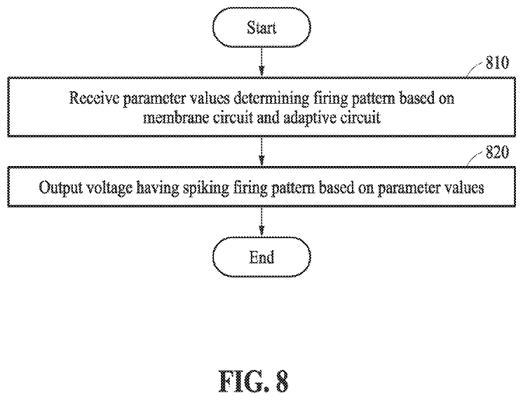

FIG. 8 illustrates an example of a method of controlling a neuron circuit, according to an example. Operations to be described hereinafter with reference to FIG. 8 may be performed sequentially, but not necessarily performed sequentially. For example, the order of the operations may be changed and at least two of the operations may be performed in parallel. A description of the operations may correspond to descriptions of the neuron circuits provided with reference to FIGS. 1 to 7.

Referring to FIG. 8, in operation 810, a neuron circuit may receive parameter values determining a firing pattern based on a membrane circuit and an adaptive circuit included in the neuron circuit. The parameter values may include τₘ that is an adaptation time constant of the membrane circuit and uᵣ that is a reset voltage of the membrane circuit described with reference to FIGS. 4A and 4B. The parameter values may include τ_{w} that is an adaptation time constant, a that is a subthreshold adaptation conductor, and b that is a spike-triggered adaptation current of the adaptive circuit described with reference to FIGS. 4A and 4B.

In operation 820, the neuron circuit may output a voltage having a spiking firing pattern based on the parameter values. The parameter values may include τₘ that is an adaptation time constant of the membrane circuit and uᵣ that is a reset voltage of the membrane circuit described with reference to FIGS. 4A and 4B. The parameter values may include τ_{w} that is an adaptation time constant, a that is a subthreshold adaptation conductor, and b that is a spike-triggered adaptation current of the adaptive circuit described with reference to FIGS. 4A and 4B. The spiking firing pattern may include an adaptive firing pattern in which a gap between output spikes increases as described with reference to FIG. 4B or a bursting firing pattern in which an output spike at a high frequency appears at the beginning of an input and the output spike no longer appears. However, the example is not limited thereto. A non-transitory computer-readable storage medium of one or more embodiments may store instructions that, when executed by one or more processors, configure the one or more processors to perform any one, combination, or all of the operations and methods of FIG. 8.

The neuron circuits, synaptic arrays, membrane circuits, comparator circuits, pulse generation circuits, adaptive circuits, pulse generation circuits, circuit parts, digital pulse generation circuits, neuron circuit 300, synaptic array 310, membrane circuit 320, comparator circuit 330, pulse generation circuit 340, adaptive circuit 350, neuron circuit 400, membrane circuit 420, adaptive circuit 450, pulse generation circuit 435, circuit part 455, digital pulse generation circuit 610, membrane circuit 720, and other apparatuses, devices, units, modules, and components disclosed and described herein with respect to FIGS. 1-8 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-8 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A neuron circuit comprising:
a membrane circuit configured to receive a weighted synaptic current from a synaptic array and receive an adaptive current from an adaptive circuit;
a comparator circuit configured to control a pulse generation circuit in response to a voltage of the membrane circuit exceeding a predetermined threshold voltage;
the pulse generation circuit configured to control the membrane circuit and the adaptive circuit based on an output signal from the comparator circuit and generate a pulse comprising a firing pattern; and
the adaptive circuit, connected to the membrane circuit and the pulse generation circuit, and configured to determine the firing pattern of the pulse generation circuit.

2. The neuron circuit of claim 1, wherein the adaptive circuit is configured to transmit an adaptive current to the membrane circuit based on an adaptation time constant parameter, a subthreshold adaptation conductor parameter, and a spike-triggered adaptation current parameter of the adaptive circuit and determine the firing pattern.

3. The neuron circuit of claim 1, wherein the membrane circuit is configured to receive the adaptive current from the adaptive circuit based on an adaptation time constant parameter of the membrane circuit and a reset voltage parameter of the membrane circuit and determine the firing pattern.

4. The neuron circuit of claim 1, wherein the membrane circuit and the adaptive circuit each comprise a variable resistor element and a capacitor element.

5. The neuron circuit of claim 4, wherein the variable resistor of the membrane circuit and the variable resistor element of the adaptive circuit each comprise either one or both of a phase change material (PCM) and resistive random access memory (RRAM).

6. The neuron circuit of claim 4, wherein the variable resistor element of the membrane circuit and the variable resistor element of the adaptive circuit each comprise an indium-gallium-zinc-oxide (IGZO) transistor.

7. The neuron circuit of claim 1, wherein the pulse generation circuit is configured to perform an operation of controlling the membrane circuit by changing a voltage of the membrane circuit to a reset voltage based on a feedback spike.

8. The neuron circuit of claim 1, wherein the pulse generation circuit is configured to perform an operation of controlling the adaptive circuit by charging an adaptive capacitor comprised in the adaptive circuit based on a feedback spike.

9. The neuron circuit of claim 1, wherein the pulse generation circuit comprises a plurality of positive channel metal-oxide semiconductors (PMOSs) and a plurality of negative channel metal-oxide semiconductors (NMOSs).

10. The neuron circuit of claim 9, wherein the pulse generation circuit is configured to perform an operation of applying a pulse to the adaptive circuit based on a common voltage and an output voltage.

11. The neuron circuit of claim 1, wherein the pulse generation circuit corresponds to a digital pulse generation circuit.

12. The neuron circuit of claim 2, wherein a voltage value of a capacitor element of the adaptive circuit is proportional to a voltage value of a capacitor element of the membrane circuit.

13. The neuron circuit of claim 2, wherein a capacitor element of the adaptive circuit is configured to decrease a voltage value of a capacitor element of the membrane circuit.

14. A processor-implemented method with neuron circuit control, the method comprising:
receiving one or more parameter values determining a firing pattern based on a membrane circuit and an adaptive circuit comprised in a neuron circuit; and
outputting a voltage comprising a spiking firing pattern based on the received one or more parameter values.

15. The neuron circuit of claim 14, wherein the one or more parameter values comprise any one or any combination of any two or more of an adaptation time constant parameter of the adaptive circuit, a reset voltage parameter of the membrane circuit, a subthreshold adaptation conductor parameter, and a spike-triggered adaptation current parameter of the adaptive circuit and determine the firing pattern.

16. A non-transitory computer-readable storage medium storing instructions that, when executed by one or more processors, configure the one or more processors to perform the method of claim 14.

17. A neuron circuit comprising:
a membrane circuit comprising a variable resistor element and configured to receive a weighted synaptic current from a synaptic array and receive an adaptive current from an adaptive circuit;
a pulse generation circuit configured to control the membrane circuit and the adaptive circuit and generate a pulse comprising a firing pattern; and
the adaptive circuit comprising another variable resistor element, connected to the membrane circuit and the pulse generation circuit, and configured to determine the firing pattern of the pulse generation circuit.

18. The neuron circuit of claim 17, further comprising a comparator circuit configured to control the pulse generation circuit in response to a voltage of the membrane circuit exceeding a predetermined threshold voltage.

19. The neuron circuit of claim 17, wherein the adaptive circuit is configured to adjust the other variable resistor element based on one or more parameters of a neuron model.

20. The neuron circuit of claim 17, wherein the membrane circuit is configured to adjust the variable resistor element based on one or more parameters of a neuron model.
